(19) United States
(12) Patent Application Publication
(10) Pub. No.: US 2025/0357904 A1
(43) Pub. Date: Nov. 20, 2025

(54) RADIO FREQUENCY AMPLIFIER SYSTEM WITH HARMONIC CONTROL

(71) Applicant: Skyworks Solutions, Inc., Irvine, CA (US)

(72) Inventors: Hyeong Tae Jeong, Westlake Village, CA (US); Khaled A. Fayed, Marion, IA (US); S. M. Shahriar Rashid, Mission Viejo, CA (US)

(21) Appl. No.: 19/212,502

(22) Filed: May 19, 2025

Related U.S. Application Data
(60) Provisional application No. 63/649,839, filed on May 20, 2024.

(51) Int. Cl. H03F 3/26; H03F 1/56

(52) U.S. Cl. CPC H03F 3/265; H03F 1/56; H03F 2200/09; H03F 2200/423; H03F 2200/451

(57) ABSTRACT

A push-pull power amplifier configured has a first transistor and a second transistor, and an output matching network coupled to the push-pull power amplifier to control a harmonic response. The output matching network includes a balun having a primary coil, each side end of which can be connected to the first transistor and the second transistor respectively, and a secondary coil electrically coupled to the primary coil. A feed circuit is connected between a center tap of the primary coil and a ground. First and second shunt capacitors are respectively disposed at each side end of the primary coil.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Field

Embodiments of the invention relate to electronic systems, and in particular, to power amplifiers for use in radio frequency (RF) electronics.

### Description of the Related Technology

Power amplifiers are used in radio frequency (RF) communication systems to amplify RF signals for transmission via antennas. It is important to manage the power of RF signal transmissions to prolong battery life and/or provide a suitable transmit power level.

Examples of RF communication systems with one or more power amplifiers include, but are not limited to, mobile phones, tablets, base stations, network access points, customer-premises equipment (CPE), laptops, and wearable electronics. For example, in wireless devices that communicate using a cellular standard, a wireless local area network (WLAN) standard, and/or any other suitable communication standard, a power amplifier can be used for RF signal amplification. An RF signal can have a frequency in the range of about 30 kHz to 300 GHz, such as in the range of about 410 MHz to about 7.125 GHz for certain communications standards.

### SUMMARY

In some aspects, the techniques described herein relate to a power amplifier system including: a push-pull power amplifier configured to amplify a radio frequency signal, the push-pull power amplifier including a first transistor and a second transistor; and an output matching network coupled to the push-pull power amplifier to control a harmonic response included in the amplified radio frequency signal, the output matching network including: a balun having a primary coil, each side end of which being connected to the first transistor and the second transistor respectively, and a secondary coil electrically coupled to the primary coil, a feed circuit connected between a center tap of the primary coil and a ground, and first and second shunt capacitors respectively disposed at each side end of the primary coil.

In some aspects, the techniques described herein relate to a power amplifier system wherein each of the first transistor and the second transistor is bipolar junction transistor (BJT).

In some aspects, the techniques described herein relate to a power amplifier system wherein a collector of the first transistor is connected to one side end of the primary coil and a collector of the second amplifier is connected to the other side end of the primary coil.

In some aspects, the techniques described herein relate to a power amplifier system further including a decoupling capacitor disposed between the side ends of the primary coil.

In some aspects, the techniques described herein relate to a power amplifier system wherein the feed circuit includes a capacitor and an inductor connected with each other in series.

In some aspects, the techniques described herein relate to a power amplifier system wherein the feed circuit is configured to operate as a short circuit at a first frequency.

In some aspects, the techniques described herein relate to a power amplifier system wherein the feed circuit is configured to operate in a resonance at a second frequency, the second frequency being double the first frequency.

In some aspects, the techniques described herein relate to a power amplifier system wherein each of the first and second shunt capacitors is configured to be tunable for wider band harmonic control.

In some aspects, the techniques described herein relate to a radio frequency module including: a packaging board configured to receive a plurality of components; a power amplifier system implemented on the packaging board, the power amplifier system including: a push-pull power amplifier configured to amplify a radio frequency signal, the push-pull power amplifier including a first transistor and a second transistor; and an output matching network coupled to the push-pull power amplifier to control a harmonic response included in the amplified radio frequency signal, the output matching network including: a balun having a primary coil, each side end of which being connected to the first transistor and the second transistor respectively, and a secondary coil electrically coupled to the primary coil, a feed circuit connected between a center tap of the primary coil and a ground, and first and second shunt capacitors respectively disposed at each side end of the primary coil.

In some aspects, the techniques described herein relate to a radio frequency module wherein the radio frequency module is a front-end module.

In some aspects, the techniques described herein relate to a radio frequency module wherein each of the first transistor and the second transistor is bipolar junction transistor (BJT).

In some aspects, the techniques described herein relate to a radio frequency module wherein a collector of the first transistor is connected to one side end of the primary coil and a collector of the second amplifier is connected to the other side end of the primary coil.

In some aspects, the techniques described herein relate to a radio frequency module wherein the power amplifier system further includes a decoupling capacitor disposed between the side ends of the primary coil.

In some aspects, the techniques described herein relate to a radio frequency module wherein the feed circuit includes a capacitor and an inductor connected with each other in series.

In some aspects, the techniques described herein relate to a radio frequency module wherein the feed circuit is configured to operate as a short circuit at a first frequency.

In some aspects, the techniques described herein relate to a radio frequency module wherein the feed circuit is configured to operate in a resonance at a second frequency, the second frequency being double the first frequency.

In some aspects, the techniques described herein relate to a radio frequency module wherein each of the first and second shunt capacitors is configured to be tunable for wider band harmonic control.

In some aspects, the techniques described herein relate to a mobile device including: a transceiver configured to generate a radio frequency signal; and a front end system including a power amplifier system configured to amplify the radio frequency signal, the power amplifier system including: a push-pull power amplifier including a first transistor and a second transistor; and an output matching network coupled to the push-pull power amplifier to control a harmonic response included in the amplified radio frequency signal, the output matching network including: a balun having a primary coil, each side end of which being connected to the first transistor and the second transistor respectively, and a secondary coil electrically coupled to the primary coil, a feed circuit connected between a center tap of the primary coil and a ground, and first and second shunt capacitors respectively disposed at each side end of the primary coil.

In some aspects, the techniques described herein relate to a mobile device wherein each of the first transistor and the second transistor is bipolar junction transistor (BJT).

In some aspects, the techniques described herein relate to a mobile device wherein a collector of the first transistor is connected to one side end of the primary coil and a collector of the second amplifier is connected to the other side end of the primary coil.

In some aspects, the techniques described herein relate to a mobile device wherein the power amplifier system further includes a decoupling capacitor disposed between the side ends of the primary coil.

In some aspects, the techniques described herein relate to a mobile device wherein the feed circuit includes a capacitor and an inductor connected with each other in series.

In some aspects, the techniques described herein relate to a mobile device wherein the feed circuit is configured to operate as a short circuit at a first frequency.

In some aspects, the techniques described herein relate to a mobile device wherein the feed circuit is configured to operate in a resonance at a second frequency, the second frequency being double the first frequency.

In some aspects, the techniques described herein relate to a mobile device wherein each of the first and second shunt capacitors is configured to be tunable for wider band harmonic control.

### BRIEF DESCRIPTION OF THE DRAWINGS

FIG. 1 is a schematic diagram of one example of a communication network.

FIG. 2A is a schematic diagram of one example of a downlink channel using multi-input and multi-output (MIMO) communications.

FIG. 2B is schematic diagram of one example of an uplink channel using MIMO communications.

FIG. 3 is a schematic diagram of one embodiment of a mobile device.

FIG. 4 is a schematic diagram of power amplifier system.

FIG. 5 shows an example of a schematic diagram of a power amplifier system 500.

FIG. 6A shows an example of a schematic diagram for equivalent circuit of the output matching network of FIG. 5 operating a fundamental frequency f0.

FIG. 6B shows an example of a schematic diagram for equivalent circuit of the output matching network of FIG. 5 operating a double fundamental frequency 2f0.

FIG. 7 shows another example of a schematic diagram of the power amplifier system 700.

FIG. 8A shows an example of schematic diagram of a power amplifier system 800 according to an embodiment of the present disclosure.

FIG. 8B shows another example of schematic diagram of a power amplifier system 800 according to an embodiment of the present disclosure.

FIG. 9A shows an example of a schematic diagram for equivalent circuit of the output matching network of FIG. 8 operating at a first frequency (f₀).

FIG. 9B shows an example of a schematic diagram for equivalent circuit of the output matching network of FIG. 8 operating at a second frequency (2f₀).

FIG. 10A shows an example of simulation result of measuring impedance of the 2nd harmonic loadline of the power amplifier system without shunt capacitors.

FIG. 10B shows an example of simulation result of measuring impedance of the 2nd harmonic loadline of the power amplifier system with shunt capacitors.

FIG. 11A is a schematic diagram of one embodiment of a packaged module.

FIG. 11B is a schematic diagram of a cross-section of the packaged module of FIG. 11A taken along the lines 11B-11B.

FIG. 11C is a schematic diagram of one embodiment of a packaged module.

FIG. 11D is a schematic diagram of a cross-section of the packaged module of FIG. 11C taken along the lines 11D-11D.

FIG. 12 is a schematic diagram of one embodiment of a phone board.

### DETAILED DESCRIPTION OF EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

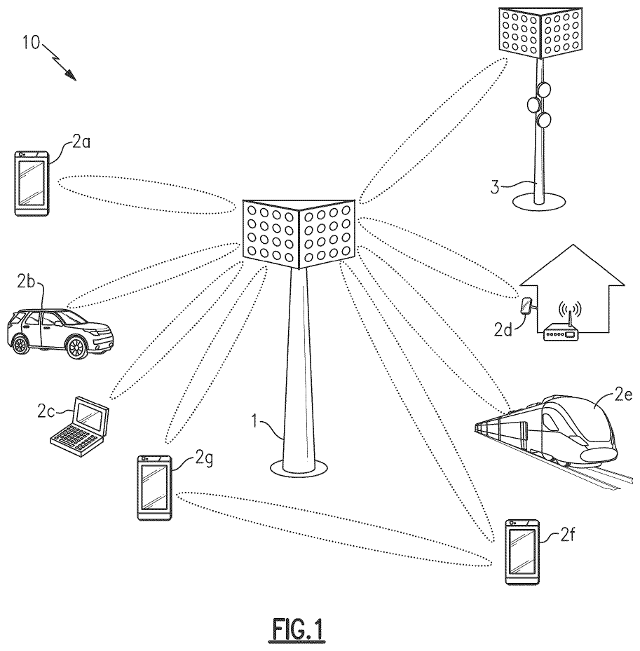

FIG. 1 is a schematic diagram of one example of a communication network 10. The communication network 10 includes a macro cell base station 1, a small cell base station 3, and various examples of user equipment (UE), including a first mobile device 2a, a wireless-connected car 2b, a laptop 2c, a stationary wireless device 2d, a wireless-connected train 2e, a second mobile device 2f, and a third mobile device 2g.

Although specific examples of base stations and user equipment are illustrated in FIG. 1, a communication network can include base stations and user equipment of a wide variety of types and/or numbers.

For instance, in the example shown, the communication network 10 includes the macro cell base station 1 and the small cell base station 3. The small cell base station 3 can operate with relatively lower power, shorter range, and/or with fewer concurrent users relative to the macro cell base station 1. The small cell base station 3 can also be referred to as a femtocell, a picocell, or a microcell. Although the communication network 10 is illustrated as including two base stations, the communication network 10 can be implemented to include more or fewer base stations and/or base stations of other types.

Although various examples of user equipment are shown, the teachings herein are applicable to a wide variety of user equipment, including, but not limited to, mobile phones, tablets, laptops, IoT devices, wearable electronics, customer premises equipment (CPE), wireless-connected vehicles, wireless relays, and/or a wide variety of other communication devices. Furthermore, user equipment includes not only currently available communication devices that operate in a cellular network, but also subsequently developed communication devices that will be readily implementable with the inventive systems, processes, methods, and devices as described and claimed herein.

The illustrated communication network 10 of FIG. 1 supports communications using a variety of cellular technologies, including, for example, 4G LTE and 5G NR. In certain implementations, the communication network 10 is further adapted to provide a wireless local area network (WLAN), such as WiFi. Although various examples of communication technologies have been provided, the communication network 10 can be adapted to support a wide variety of communication technologies.

Various communication links of the communication network 10 have been depicted in FIG. 1. The communication links can be duplexed in a wide variety of ways, including, for example, using frequency-division duplexing (FDD) and/or time-division duplexing (TDD). FDD is a type of radio frequency communications that uses different frequencies for transmitting and receiving signals. FDD can provide a number of advantages, such as high data rates and low latency. In contrast, TDD is a type of radio frequency communications that uses about the same frequency for transmitting and receiving signals, and in which transmit and receive communications are switched in time. TDD can provide a number of advantages, such as efficient use of spectrum and variable allocation of throughput between transmit and receive directions.

In certain implementations, user equipment can communicate with a base station using one or more of 4G LTE, 5G NR, and WiFi technologies. In certain implementations, enhanced license assisted access (eLAA) is used to aggregate one or more licensed frequency carriers (for instance, licensed 4G LTE and/or 5G NR frequencies), with one or more unlicensed carriers (for instance, unlicensed WiFi frequencies).

As shown in FIG. 1, the communication links include not only communication links between UE and base stations, but also UE to UE communications and base station to base station communications. For example, the communication network 30 can be implemented to support self-fronthaul and/or self-backhaul (for instance, as between mobile device 32g and mobile device 32f).

The communication links can operate over a wide variety of frequencies. In certain implementations, communications are supported using 5G NR technology over one or more frequency bands that are less than 6 Gigahertz (GHz) and/or over one or more frequency bands that are greater than 6 GHz. For example, the communication links can serve Frequency Range 1 (FR1), Frequency Range 2 (FR2), or a combination thereof. In one embodiment, one or more of the mobile devices support a HPUE power class specification.

In certain implementations, a base station and/or user equipment communicates using beamforming. For example, beamforming can be used to focus signal strength to overcome path losses, such as high loss associated with communicating over high signal frequencies. In certain embodiments, user equipment, such as one or more mobile phones, communicate using beamforming on millimeter wave frequency bands in the range of 30 GHz to 300 GHz and/or upper centimeter wave frequencies in the range of 6 GHz to 30 GHz, or more particularly, 24 GHz to 30 GHz.

Different users of the communication network 30 can share available network resources, such as available frequency spectrum, in a wide variety of ways.

In one example, frequency division multiple access (FDMA) is used to divide a frequency band into multiple frequency carriers. Additionally, one or more carriers are allocated to a particular user. Examples of FDMA include, but are not limited to, single carrier FDMA (SC-FDMA) and orthogonal FDMA (OFDMA). OFDMA is a multicarrier technology that subdivides the available bandwidth into multiple mutually orthogonal narrowband subcarriers, which can be separately assigned to different users.

Other examples of shared access include, but are not limited to, time division multiple access (TDMA) in which a user is allocated particular time slots for using a frequency resource, code division multiple access (CDMA) in which a frequency resource is shared amongst different users by assigning each user a unique code, space-divisional multiple access (SDMA) in which beamforming is used to provide shared access by spatial division, and non-orthogonal multiple access (NOMA) in which the power domain is used for multiple access. For example, NOMA can be used to serve multiple users at the same frequency, time, and/or code, but with different power levels.

Enhanced mobile broadband (eMBB) refers to technology for growing system capacity of LTE networks. For example, eMBB can refer to communications with a peak data rate of at least 10 Gbps and a minimum of 100 Mbps for each user. Ultra-reliable low latency communications (uRLLC) refers to technology for communication with very low latency, for instance, less than 2 milliseconds. uRLLC can be used for mission-critical communications such as for autonomous driving and/or remote surgery applications. Massive machine-type communications (mMTC) refers to low cost and low data rate communications associated with wireless connections to everyday objects, such as those associated with Internet of Things (IoT) applications.

The communication network 30 of FIG. 1 can be used to support a wide variety of advanced communication features, including, but not limited to, eMBB, uRLLC, and/or mMTC.

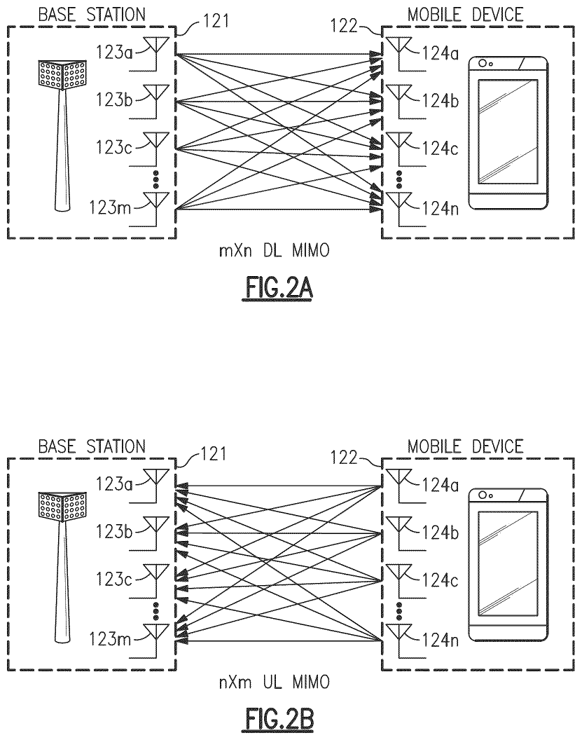

FIG. 2A is a schematic diagram of one example of a downlink channel using multi-input and multi-output (MIMO) communications. FIG. 2B is a schematic diagram of one example of an uplink channel using MIMO communications.

MIMO communications use multiple antennas for simultaneously communicating multiple data streams over common frequency spectrum. In certain implementations, the data streams operate with different reference signals to enhance data reception at the receiver. MIMO communications benefit from higher SNR, improved coding, and/or reduced signal interference due to spatial multiplexing differences of the radio environment.

MIMO order refers to a number of separate data streams sent or received. For instance, MIMO order for downlink communications can be described by a number of transmit antennas of a base station and a number of receive antennas for UE, such as a mobile device. For example, two-by-two (2×2) DL MIMO refers to MIMO downlink communications using two base station antennas and two UE antennas. Additionally, four-by-four (4×4) DL MIMO refers to MIMO downlink communications using four base station antennas and four UE antennas.

In the example shown in FIG. 2A, downlink MIMO communications are provided by transmitting using M antennas 123a, 123b, 123c, . . . 123m of the base station 121 and receiving using N antennas 124a, 124b, 124c, . . . 124n of the mobile device 122. Accordingly, FIG. 2A illustrates an example of m×n DL MIMO.

Likewise, MIMO order for uplink communications can be described by a number of transmit antennas of UE, such as a mobile device, and a number of receive antennas of a base station. For example, 2×2 UL MIMO refers to MIMO uplink communications using two UE antennas and two base station antennas. Additionally, 4×4 UL MIMO refers to MIMO uplink communications using four UE antennas and four base station antennas.

In the example shown in FIG. 2B, uplink MIMO communications are provided by transmitting using N antennas 124a, 124b, 124c, . . . 124n of the mobile device 122 and receiving using M antennas 123a, 123b, 123c, . . . 123m of the base station 121. Accordingly, FIG. 2B illustrates an example of n×m UL MIMO.

By increasing the level or order of MIMO, bandwidth of an uplink channel and/or a downlink channel can be increased.

MIMO communications are applicable to communication links of a variety of types, such as FDD communication links and TDD communication links.

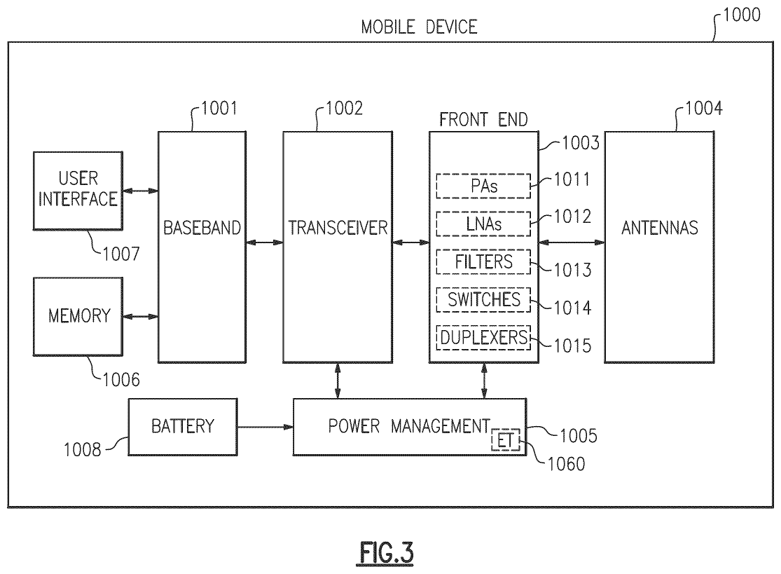

FIG. 3 is a schematic diagram of one example of a mobile device 1000.

The mobile device 1000 includes a baseband system 1001, a transceiver 1002, a front end system 1003, antennas 1004, a power management system 1005, a memory 1006, a user interface 1007, and a battery 1008.

The mobile device 1000 can be used communicate using a wide variety of communications technologies, including, but not limited to, 2G, 3G, 4G (including LTE, LTE-Advanced, and LTE-Advanced Pro), 5G, WLAN (for instance, Wi-Fi), WPAN (for instance, Bluetooth and ZigBee), WMAN (for instance, WiMax), and/or GPS technologies.

The transceiver 1002 generates RF signals for transmission and processes incoming RF signals received from the antennas 1004. It will be understood that various functionalities associated with the transmission and receiving of RF signals can be achieved by one or more components that are collectively represented in FIG. 3 as the transceiver 1002. In one example, separate components (for instance, separate circuits or dies) can be provided for handling certain types of RF signals.

The front end system 1003 aids in conditioning signals transmitted to and/or received from the antennas 1004. In the illustrated embodiment, the front end system 1003 includes power amplifiers (PAS) 1011, low noise amplifiers (LNAs) 1012, filters 1013, switches 1014, and duplexers 1015. However, other implementations are possible.

For example, the front end system 1003 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 1000 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band and/or in different bands.

The antennas 1004 can include antennas used for a wide variety of types of communications. For example, the antennas 1004 can include antennas associated transmitting and/or receiving signals associated with a wide variety of frequencies and communications standards.

In certain implementations, the antennas 1004 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 1000 can operate with beamforming in certain implementations. For example, the front end system 1003 can include phase shifters having variable phase controlled by the transceiver 1002. Additionally, the phase shifters are controlled to provide beam formation and directivity for transmission and/or reception of signals using the antennas 1004. For example, in the context of signal transmission, the phases of the transmit signals provided to the antennas 1004 are controlled such that radiated signals from the antennas 1004 combine using constructive and destructive interference to generate an aggregate transmit signal exhibiting beam-like qualities with more signal strength propagating in a given direction. In the context of signal reception, the phases are controlled such that more signal energy is received when the signal is arriving to the antennas 1004 from a particular direction. In certain implementations, the antennas 1004 include one or more arrays of antenna elements to enhance beamforming.

The baseband system 1001 is coupled to the user interface 1007 to facilitate processing of various user input and output (I/O), such as voice and data. The baseband system 1001 provides the transceiver 1002 with digital representations of transmit signals, which the transceiver 1002 processes to generate RF signals for transmission. The baseband system 1001 also processes digital representations of received signals provided by the transceiver 1002. As shown in FIG. 3, the baseband system 1001 is coupled to the memory 1006 of facilitate operation of the mobile device 1000.

The memory 1006 can be used for a wide variety of purposes, such as storing data and/or instructions to facilitate the operation of the mobile device 1000 and/or to provide storage of user information.

The power management system 1005 provides a number of power management functions of the mobile device 1000. The power management system 1005 of FIG. 3 includes an envelope tracker 1060. As shown in FIG. 3, the power management system 1005 receives a battery voltage form the battery 1008. The battery 1008 can be any suitable battery for use in the mobile device 1000, including, for example, a lithium-ion battery.

The mobile device 1000 of FIG. 3 illustrates one example of an RF communication system that can include power amplifier(s) implemented in accordance with one or more features of the present disclosure. However, the teachings herein are applicable to RF communication systems implemented in a wide variety of ways.

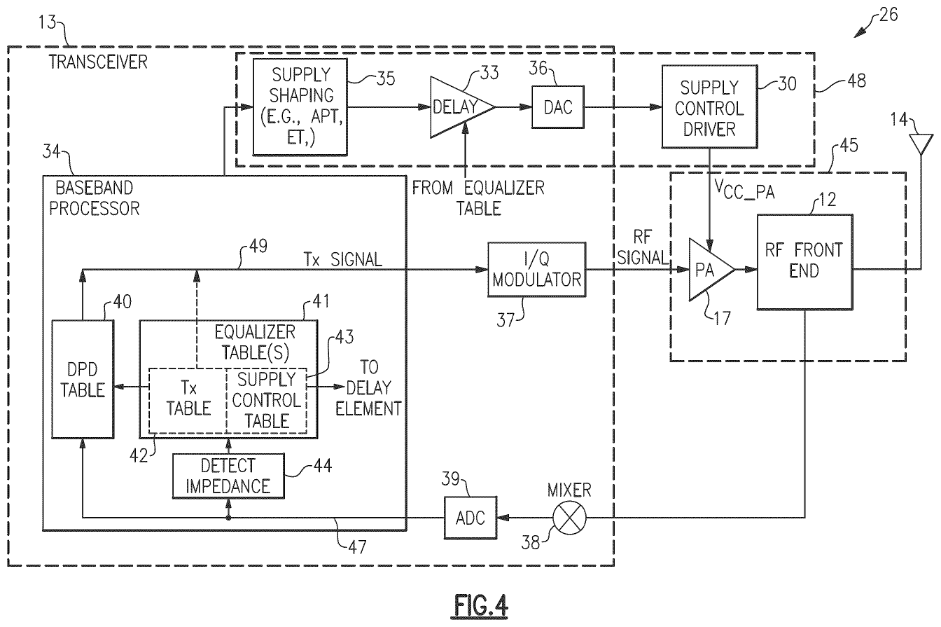

FIG. 4 is a detailed block diagram of one example of a power amplifier system 26. For example, the power amplifier system 26 may be incorporated into the mobile device 1000. The illustrated power amplifier system 26 includes an RF front end 12, an antenna 14, a battery 21, a supply control driver 30, a power amplifier 17, and a transceiver 13. The illustrated transceiver 13 includes a baseband processor 34, a supplying shaping block or circuit 35, a delay component 33, a digital-to-analog converter (DAC) 36, a quadrature (I/Q) modulator 37, a mixer 38, and an analog-to-digital converter (ADC) 39. The supply shaping block 35, delay component 33, DAC 36, and supply control driver 30 together form a supply shaping branch 48.

The baseband processor 34 can be used to generate an I signal and a Q signal, which correspond to signal components of a sinusoidal wave or signal of a desired amplitude, frequency, and phase. For example, the I signal can be used to represent an in-phase component of the sinusoidal wave and the Q signal can be used to represent a quadrature component of the sinusoidal wave, which can be an equivalent representation of the sinusoidal wave. In certain implementations, the I and Q signals can be provided to the I/Q modulator 37 in a digital format. The baseband processor 34 can be any suitable processor configured to process a baseband signal. For instance, the baseband processor 34 can include a digital signal processor, a microprocessor, a programmable core, or any combination thereof. Moreover, in some implementations, two or more baseband processors 34 can be included in the power amplifier system 26.

The I/Q modulator 37 can be configured to receive the I and Q signals from the baseband processor 34 and to process the I and Q signals to generate an RF signal. For example, the I/Q modulator 37 can include DACs configured to convert the I and Q signals into an analog format, mixers for upconverting the I and Q signals to radio frequency, and a signal combiner for combining the upconverted I and Q signals into an RF signal suitable for amplification by the power amplifier 17. In certain implementations, the I/Q modulator 37 can include one or more filters configured to filter frequency content of signals processed therein.

The supply shaping block 35 can be used to convert an envelope or amplitude signal associated with the I and Q signals into a shaped power supply control signal, such as an average power tracking (APT) signal or an envelope tracking (ET) signal, depending on the embodiment. Shaping the envelope signal from the baseband processor 34 can aid in enhancing performance of the power amplifier system 26. In certain implementations, such as where the supplying shaping block is configured to implement an envelope tracking function, the supply shaping block 35 is a digital circuit configured to generate a digital shaped envelope signal, and the DAC 36 is used to convert the digital shaped envelope signal into an analog shaped envelope signal suitable for use by the supply control driver 30. However, in other implementations, the DAC 36 can be omitted in favor of providing the supply control driver 30 with a digital envelope signal to aid the supply control driver 30 in further processing of the envelope signal.

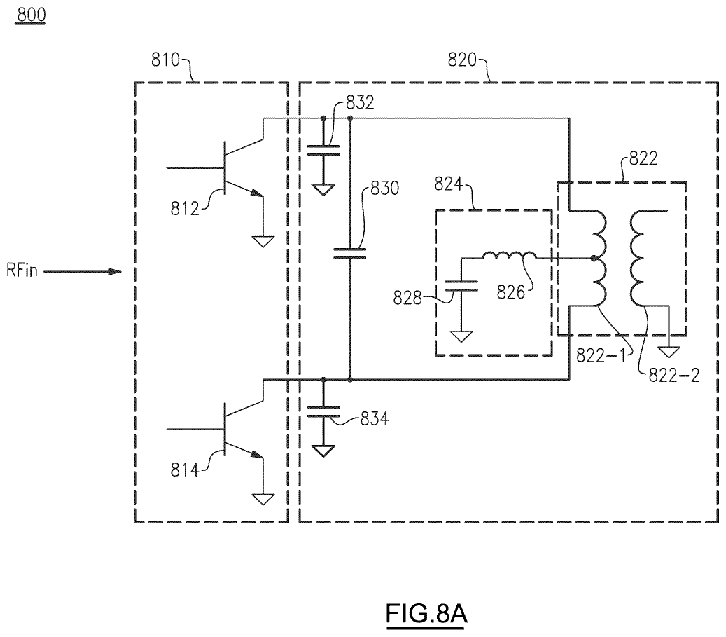

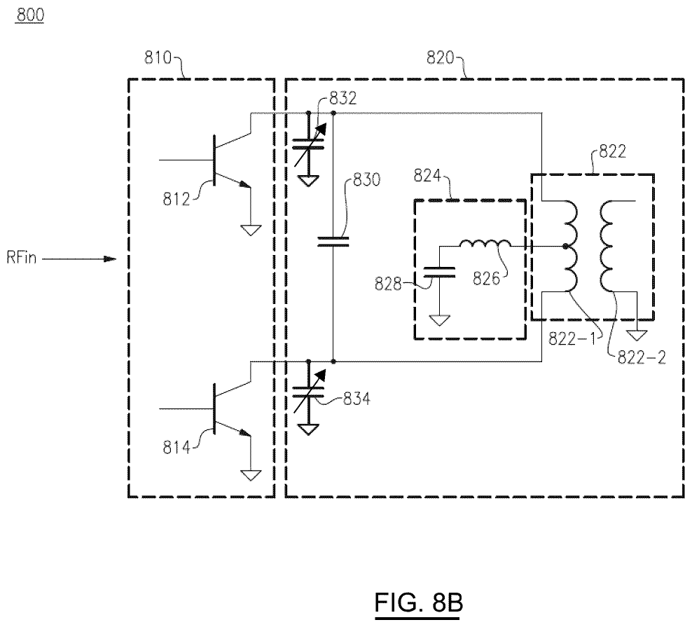

The supply control driver 30 can receive the supply control signal (e.g., an analog shaped envelope signal or APT signal) from the transceiver 13 and a battery voltage VBATT from the battery 21, and can use the supply control signal to generate a power amplifier supply voltage VCC_PA for the power amplifier 17 that changes in relation to the transmit signal. The power amplifier 17 can receive the RF transmit signal from the I/Q modulator 37 of the transceiver 13, and can provide an amplified RF signal to the antenna 14 through the RF front end 12. In other cases, a fixed power amplifier supply voltage VCC_PA is provided to the power amplifier 17. In some such embodiments, one or more of the supply shaping block 35, DAC 36, and supply control driver 30 may not be included. Exemplary waveforms of power amplifier supply voltage VCC_PA and corresponding RF transmit signals are shown in FIGS. 8A, 8B, and 8C for fixed supply, APT, and ET power supply control operations, respectively. In some embodiments, the power amplifier system 26 is capable of performing two or more supply control techniques. For instance, the power amplifier system 26 allows for selection (e.g., via firmware programming or other appropriate mechanism) of two or more of ET, APT, and fixed power supply control modes. In such cases, the baseband processor or other appropriate controller or processor may instruct the supply shaping block 35 to enter into the appropriate selected mode.

The delay component 33 implements a selectable delay in the supply control path. As will be described in further detail, this can be useful in some cases for compensating for non-linearities and/or other potential sources of signal degradation. The illustrated delay component is shown in the digital domain as part of the transceiver 13, and may comprise a FIFO or other type of memory-based delay element. However, the delay component 33 can be implemented in any appropriate fashion, and in other embodiments may be integrated as part of the supply shaping block 35, or may be implemented in the analog domain, after the DAC 36, for example.

The RF front end 12 receives the output of the power amplifier 17, and can include a variety of components including one or more duplexers, switches (e.g., formed in an antenna switch module), directional couplers, and the like.

The directional coupler (not shown) within the RF front end 12 can be a dual directional coupler or other appropriate coupler or other device capable of providing a sensed output signal to the mixer 38. According to certain embodiments, including the illustrated embodiment, the directional coupler is capable of providing both incident and reflected signals (e.g., forward and reverse power) to the mixer 38. For instance, the directional coupler can have at least four ports, which may include an input port configured to receive signals generated by the power amplifier 17, an output port coupled to the antenna 14, a first measurement port configured to provide forward power to the mixer 38, and a second measurement port configured to provide reverse power to the mixer 38.

The mixer 38 can multiply the sensed output signal by a reference signal of a controlled frequency (not illustrated in FIG. 4) so as to downshift the frequency spectrum of the sensed output signal. The downshifted signal can be provided to the ADC 39, which can convert the downshifted signal to a feedback signal 47 in a digital format suitable for processing by the baseband processor 34. As will be discussed in further detail, by including a feedback path between the output of the power amplifier 17 and an input of the baseband processor 34, the baseband processor 34 can be configured to dynamically adjust the I and Q signals and/or power control signal associated with the I and Q signals to optimize the operation of the power amplifier system 26. For example, configuring the power amplifier system 26 in this manner can aid in controlling the power added efficiency (PAE) and/or linearity of the power amplifier 32. The mixer 38, ADC 39 and/or other appropriate componentry may generally perform a quadrature (I/Q) demodulation function in some embodiments.

Although the power amplifier system 26 is illustrated as include a single power amplifier, the teachings herein are applicable to power amplifier systems including multiple power amplifiers, including, for example, multi-mode and/or multi-mode power amplifier systems.

Additionally, although FIG. 4 illustrates a particular configuration of a transceiver, other configurations are possible, including for example, configurations in which the transceiver 13 includes more or fewer components and/or a different arrangement of components.

As shown the baseband processor 34 can include a digital pre-distortion (DPD) table 40, an equalizer table 41, and a complex impedance detector 44. The DPT table 40 may be stored in a non-volatile memory (e.g., flash memory, read only memory (ROM), etc.) of the transceiver 34 that is accessible by the baseband processor 34. According to some embodiments, the baseband processor 34 accesses entries in the DPD table 40 to aid in linearizing the power amplifier 17. For instance, the baseband processor 34 selects appropriate entries in the DPD table 40 based on the sensed feedback signal 47, and adjusts the transmit signal accordingly, prior to outputting the transmit signal to the I/Q modulator 37. For example, DPD can be used to compensate for certain nonlinear effects of the power amplifier 17, including, for example, signal constellation distortion and/or signal spectrum spreading. According to certain embodiments including the illustrated embodiment, the DPD table 40 implements memoryless DPD, e.g., where the current output of the DPD corrected transmit signal depends only on the current input.

FIG. 5 shows an example of a schematic diagram of a power amplifier system 500. As shown in FIG. 5, the power amplifier system 500 includes a power amplifier stage 510 and an output matching network 520.

The power amplifier stage 510 may be configured to amplify a radio frequency signal. The radio frequency signal may be provided from a transceiver (not shown in FIG. 5). According to an embodiment, the power amplifier stage 510 may be a push-pull power amplifier. The power amplifier stage 510 may include a first transistor 512 and a second transistor 514. Each of the first transistor 512 and the second transistor 514 may be a bipolar junction transistor (BJT). The first transistor 512 may be referred to as a common emitter transistor, and the second transistor 514 may be referred to as a common base transistor. Each of collectors of the first transistor 512 and the second transistor 514 may be connected to the output matching network 520 to provide the amplified radio frequency signal.

The output matching network 520 is coupled to the power amplifier stage 510. The output matching network 520 may include 522 a balun having a primary coil 522-1 and a secondary coil 522-2. The primary coil 522-1 and the secondary coil 522-2 are electrically coupled to each other. One side end of the primary coil 522-1 may be connected to the collector of the first transistor 512. The other side end of the primary coil 522-1 may be connected to the collector of the second transistor 514.

The output matching network 520 may further include a feed circuit 524 connected between a center tap of the primary coil 522-1 and a ground. According to an embodiment, the output matching network 520 may include an inductor 526 and a capacitor 528 connected in series (LC series circuit), and further include a capacitor 530 connected to the LC series circuit in parallel. Each of the end of the capacitor 530 and the LC series circuit may be connected to the ground.

The output matching network 520 may further include a decoupling capacitor 532 connected between the two side ends of the primary coil 522-1. That is, the decoupling capacitor 532 may connect the collectors of the first transistor 512 and the second transistor 514.

Meanwhile, an active element used for the power amplifier, for example, BJT, FET or MOSFET, may not equally amplify every frequency component in the input waveform and it may cause non-linearity. Harmonic distortion in the power amplifier is mainly caused by the non-linearity of the active elements. That is, the harmonic distortions is the distortion in output waveform due to the generation of harmonics.

In response to this harmonic distortion, the feed circuit 524 may be configured to operate as a 2f₀ (double fundamental frequency) control block. In this case, the LC series circuit may be referred to as a f₀ tank. That is, the feed circuit 524 may act differently depending on the operating frequency, for example, f₀ or 2f₀.

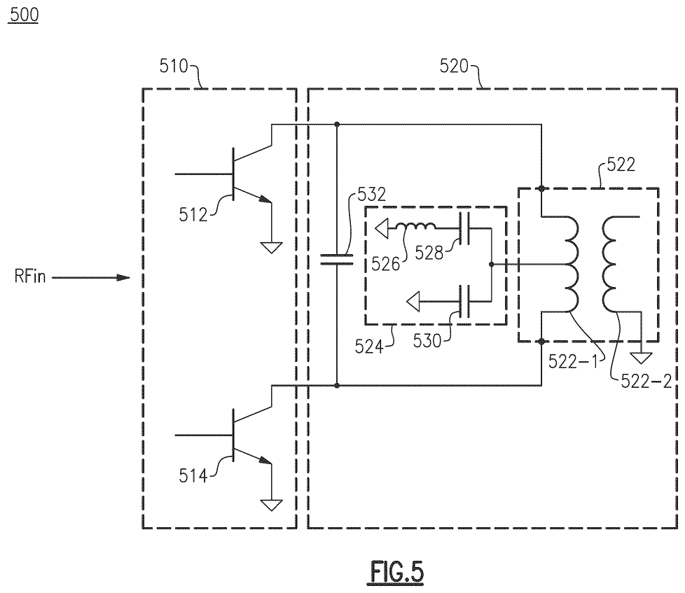

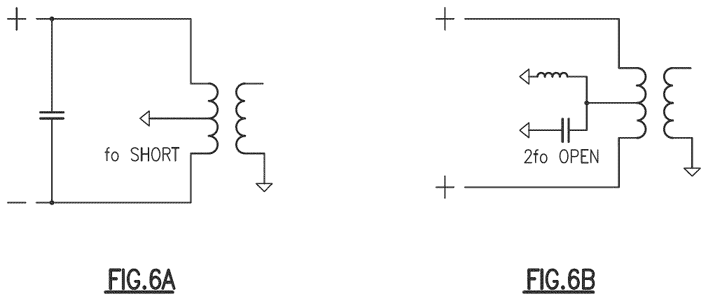

FIG. 6A shows an example of a schematic diagram for equivalent circuit of the output matching network of FIG. 5 operating a fundamental frequency f₀. FIG. 6B shows an example of a schematic diagram for equivalent circuit of the output matching network of FIG. 5 operating a double fundamental frequency 2f₀.

As shown in FIG. 6A, the feed circuit 524 may be equivalent to a short circuit when the power amplifier system 500 is operating at the fundamental frequency f₀. As shown in FIG. 6B, the feed circuit 524 may be equivalent to an open circuit when the power amplifier system 500 is operating at twice the fundamental frequency 2f₀.

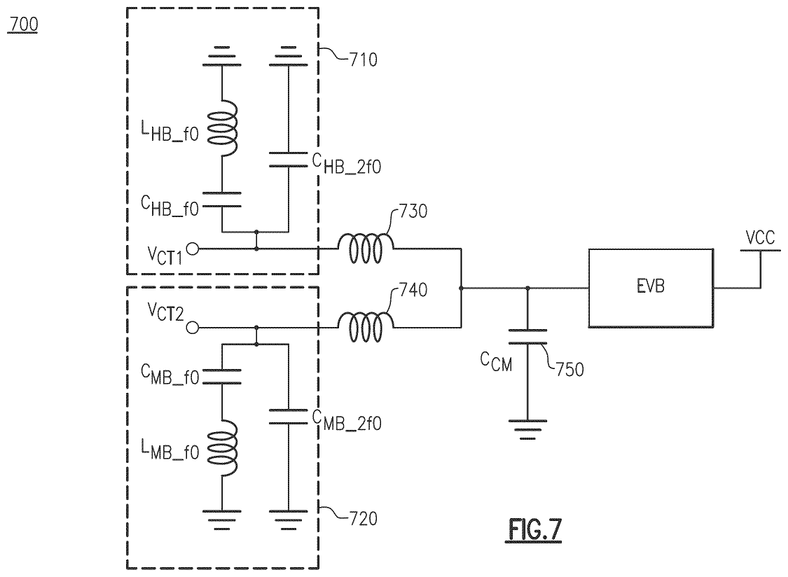

FIG. 7 shows another example of a schematic diagram of the power amplifier system 700. In FIG. 7, the power amplifier system 700 may be configured to be connected to a multiple number of power amplifiers.

For example, the power amplifier system 700 may include a first feed circuit 710 configured to be connected to a first power amplifier (not shown). The power amplifier system 700 may further include a second feed circuit 720 configured to be connected to a second power amplifier (now shown). According to an embodiment, the first feed circuit 710 may operate as a 2f₀ control block for band A, and the second feed circuit 720 may operate as a 2f₀ control block for band B.

The first feed circuit 710 and the second feed circuit 720 may be connected to a first branch-out inductor 730 and a second branch-out inductor 740, respectively. The power amplifier system 700 may further include a common decoupling capacitor 750. As shown in FIG. 7, both first feed circuit 710 and second feed circuit 720 share a common Vcc path for the respective amplifiers.

5G front-end modules within 5G communication systems play a pivotal role in advancing 5G technology, with a particular emphasis on the integral significance of the power amplifier (PA). The PA assumes a critical function, notably in achieving heightened power added efficiency (PAE) and adjacent channel leakage ratio (ACLR), i.e., optimal linearity for a diverse array of applications. The efficacy of the PA is intricately linked to the impedance of the supply network across varying frequencies, thereby directly influencing PA performance metrics encompassing power added efficiency.

Traditional paradigms involved the utilization of distinct supply sources within the phone module, each catering to individual PAs. However, with the proliferation of 5G technology, the demand for numerous communication bands has surged, complicating matters given the availability of just a singular supply source. In response, the present disclosure introduces an innovative harmonic terminations for power amplifier, tailored specifically to cater to the requirements of PAs, for example, inverse class-F PAs. This groundbreaking approach acts as a keystone, significantly elevating both PAE and ACLR across a spectrum of bands.

Notably, the harmonic termination networks, constituting a main part of the PA system, extend their influence beyond enhancing PAE and ACLR. They concurrently maintain a low impedance profile at envelope frequencies, spanning the collector and power supply de-coupling cap. This dual-faceted effect not only curbs memory distortion but also facilitates distortion-free wideband modulation, a very important facet for seamless 5G application deployment.

In this disclosure, the presented solution introduces an innovative approach for controlling the harmonics of Push-Pull Power Amplifiers (PAs) through the utilization of a single-ended shunt capacitor positioned at the collector. This technique offers a simplified means of harmonics control in comparison to conventional methods.

It is imperative to acknowledge that while inverse-F power amplifiers do indeed offer the benefits, they are also accompanied by specific intricacies and challenges pertaining to their design. In this disclosure, the introduced single-ended shunt capacitor serves to mitigate the impact of parasitic inductance inherent in balun transformers, effectively achieving resonance and generating a high impedance at twice the fundamental frequency (2f0).

The innovation presented herein represents a significant advancement in the realm of harmonic control for Push-Pull Power Amplifiers, offering a more straightforward yet effective solution to address the challenges associated with harmonic content management.

FIG. 8A shows an example of schematic diagram of a power amplifier system 800 according to an embodiment of the present disclosure. As shown in FIG. 8A, the power amplifier system 800 includes a power amplifier stage 810 and an output matching network 820.

The power amplifier stage 810 may be configured to amplify a radio frequency signal. The radio frequency signal may be provided from a transceiver (not shown in FIG. 8). According to an embodiment, the power amplifier stage 810 may be a push-pull power amplifier. The power amplifier stage 810 may include a first transistor 812 and a second transistor 814. Each of the first transistor 812 and the second transistor 814 may be a bipolar junction transistor (BJT). However, according to another example, the first transistor 812 and the second transistor 814 may be different type of transistors, for example FET, MOSFET.

The first transistor 812 may be referred to as a common emitter transistor, and the second transistor 814 may be referred to as a common base transistor. Each of the emitters of the first transistor and the second transistor 814 may be connected to the ground. Each of collectors of the first transistor 812 and the second transistor 814 may be connected to the output matching network 820 to provide the amplified radio frequency signal.

The output matching network 820 is coupled to the power amplifier stage 810 to control harmonic distortion generated by the power amplifier stage 810. That is, the output matching network 820 may be configured to control the harmonic response included in the amplified radio frequency signal. The output matching network 820 may include 822 a balun having a primary coil 822-1 and a secondary coil 822-2. The primary coil 822-1 and the secondary coil 822-2 may be electrically coupled to each other. One side end of the primary coil 822-1 may be connected to the collector of the first transistor 812. The other side end of the primary coil 822-1 may be connected to the collector of the second transistor 814.

The output matching network 820 may further include a feed circuit 824 connected between a center tap of the primary coil 822-1 and a ground. According to an embodiment, the output matching network 820 may include an inductor 826 and a capacitor 828 connected in series (LC series circuit). One end of the LC series circuit may be connected to the ground.

The output matching network 820 may further include a decoupling capacitor 830 connected between the two side ends of the primary coil 822-1. That is, the decoupling capacitor 830 may connect the collectors of the first transistor 812 and the second transistor 814.

According to an embodiment of the present disclosure, the power amplifier system 800 may further includes a first shunt capacitor 832 and a second shunt capacitor 834. The first shunt capacitor 832 and the second shunt capacitor 834 may be disposed, respectively, at each side end of the primary coil 822-1. The first shunt capacitor 832 may be disposed between the collector of the first transistor 812 and the ground, and the second shunt capacitor 834 may be disposed between the collector of the second transistor 814 and the ground.

According to embodiments of the present disclosure, the first shunt capacitor 832 and the second shunt capacitor 834 may be configured to be tunable for wider band harmonic control. For example, FIG. 8B shows an example of schematic diagram of a power amplifier system 800 including a tunable first shunt capacitor 832 and a tunable second shunt capacitor 834.

According to embodiments of the present disclosure, superior harmonic termination characteristics can be achieved while mitigating concerns related to parasitic loss. Furthermore, it enables to easily implement wideband operation using variable capacitor, thus marking a substantial improvement over existing techniques.

Moreover, it provides precise control over the phase of the 2nd harmonic load line (LL), surpassing the restricted control range of the conventional technique. This enhancement facilitates the optimization of power amplifier performance to achieve the most favorable power-added efficiency (PAE) load line. Additionally, the finely tuned control achievable with the disclosed method has the capacity to elevate the performance of the Adjacent Channel Leakage Ratio (ACLR).

FIG. 9A shows an example of a schematic diagram for equivalent circuit of the output matching network of FIG. 8 operating a fundamental frequency f₀ (referred to as a first frequency). FIG. 9B shows an example of a schematic diagram for equivalent circuit of the output matching network of FIG. 8 operating a double fundamental frequency 2f₀ (referred to as a second frequency).

As shown in FIG. 9A, the feed circuit 824 may be equivalent to a short circuit when the power amplifier system 800 is operating at the fundamental frequency f₀. As shown in FIG. 9B, the feed circuit 824 may be equivalent to an inductor when the power amplifier system 900 is operating at twice the fundamental frequency 2f₀. More specifically, the feed circuit 824 may be configured to achieve a resonance at the second frequency (2f₀).

The first and the second shunt capacitors 832, 834 may mitigate the impact of parasitic inductance inherent in the balun transformers, and effectively achieving resonance and generating a high impedance at the second frequency (2f₀).

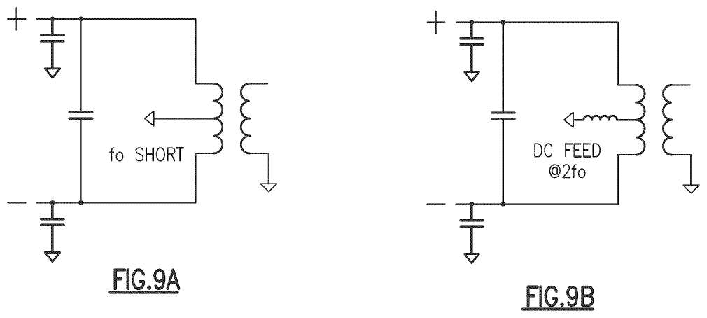

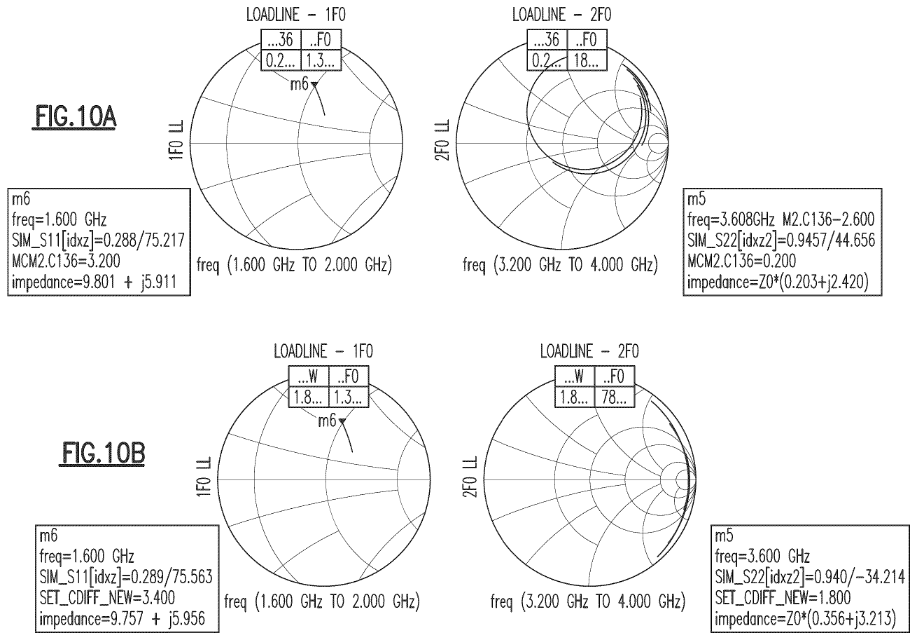

FIG. 10A shows an example of simulation result of measuring impedance of the 2^{nd} harmonic loadline of the power amplifier system 500 without shunt capacitors. FIG. 10B shows an example of simulation result of measuring impedance of the 2^{nd} harmonic loadline of the power amplifier system 800 with shunt capacitors. As shown in FIG. 10B, the impedance of the loadline of the power amplifier system with the shunt capacitors has much less impedance which cause less distortions.

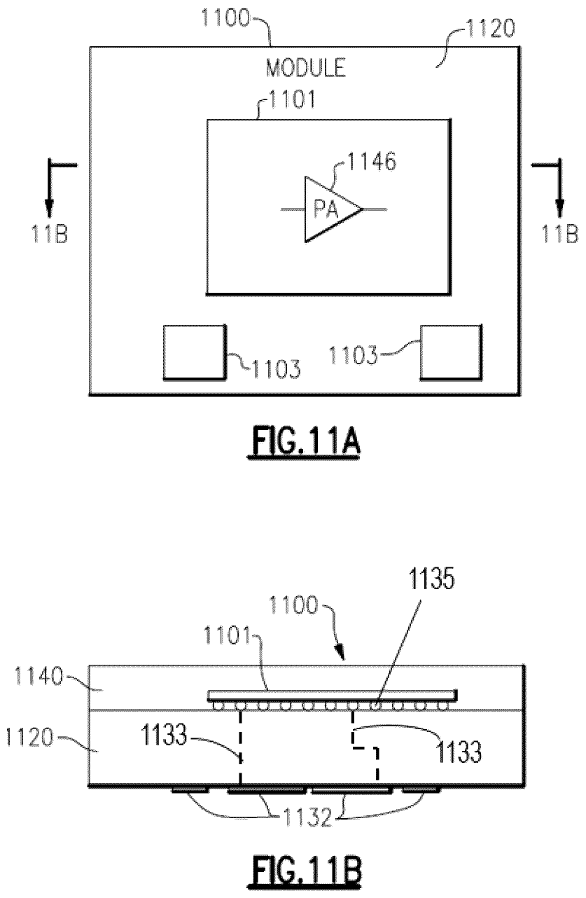

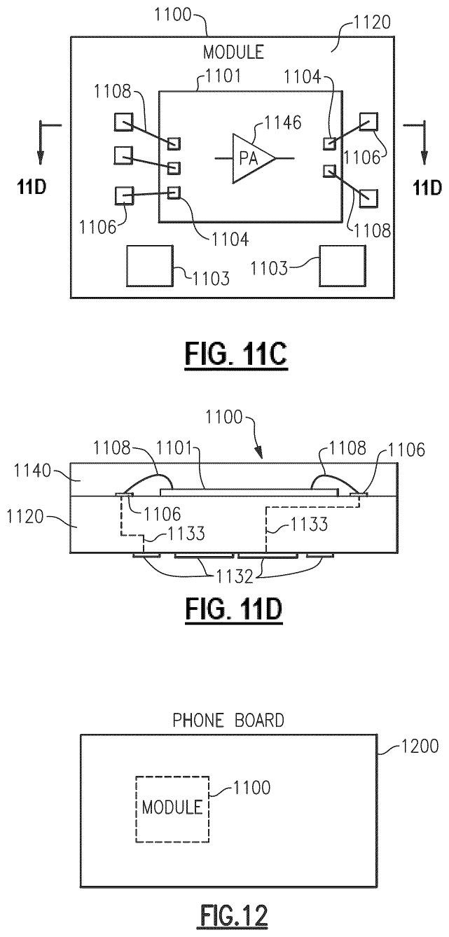

FIG. 11A is a schematic diagram of one embodiment of a packaged module 800. FIG. 11B is a schematic diagram of a cross-section of the packaged module 1100 of FIG. 11A taken along the lines 11B-11B.

The packaged module 1100 includes an IC or die 1101, surface mount components 1103, a package substrate 1120, and encapsulation structure 1140. Additionally, the die 1101 includes flip-chip contacts 1135 (e.g., a ball grid array), that electrically connect the die 1101 to corresponding contacts (not shown) on the package substrate 1101.

The die 1101 includes a power amplifier system 800, which can be implemented in accordance with any of the embodiments herein.

The packaging substrate 1120 can be configured to receive a plurality of components such as the die 1101 and the surface mount components 1103, which can include, for example, surface mount capacitors and/or inductors.

As shown in FIG. 11B, the packaged module 1100 is shown to include a plurality of contact pads 1132 disposed on the side of the packaged module 1100 opposite the side used to mount the die 1101. Configuring the packaged module 1100 in this manner can aid in connecting the packaged module 1100 to a circuit board such as a phone board of a wireless device. The example contact pads 1132 can be configured to provide RF signals, bias signals, power low voltage(s) and/or power high voltage(s) to the die 1101 and/or the surface mount components 1103. As shown in FIG. 11B, the electrically connections between the contact pads 1132 and the die 1101 can be facilitated by connections 1133 through the package substrate 1120. The connections 1133 can represent electrical paths formed through the package substrate 1120, such as connections associated with vias and conductors of a multilayer laminated package substrate.

In some embodiments, the packaged module 1100 can also include one or more packaging structures to, for example, provide protection and/or facilitate handling of the packaged module 1100. Such a packaging structure can include overmold or encapsulation structure 1140 formed over the packaging substrate 1120 and the components and die(s) disposed thereon.

It will be understood that although the packaged module 1100 is described in the context of electrical connections based on a flip-chip configuration, one or more features of the present disclosure can also be implemented in other packaging configurations, including, for example, wire-bond configurations.

For example, FIG. 11C is a schematic diagram of one embodiment of a packaged module 800 implementing wire bond attachment. FIG. 11C is a schematic diagram of a cross-section of the packaged module 1100 of FIG. 11C taken along the lines 11D-11D.

The packaged module 1100 includes an IC or die 1101, surface mount components 1103, wirebonds 1108, a package substrate 1120, and encapsulation structure 1140. The package substrate 1120 includes pads 1106 formed from conductors disposed therein. Additionally, the die 1101 includes pads 1104, and the wirebonds 1108 have been used to electrically connect the pads 1104 of the die 1101 to the pads 1106 of the package substrate 1101.

The die 1101 includes a power amplifier system 800, which can be implemented in accordance with any of the embodiments herein.

The packaging substrate 1120 can be configured to receive a plurality of components such as the die 1101 and the surface mount components 1103, which can include, for example, surface mount capacitors and/or inductors.

As shown in FIG. 11D, the packaged module 1100 is shown to include a plurality of contact pads 1132 disposed on the side of the packaged module 1100 opposite the side used to mount the die 1101. Configuring the packaged module 1100 in this manner can aid in connecting the packaged module 1100 to a circuit board such as a phone board of a wireless device. The example contact pads 1132 can be configured to provide RF signals, bias signals, power low voltage(s) and/or power high voltage(s) to the die 1101 and/or the surface mount components 1103. As shown in FIG. 11B, the electrically connections between the contact pads 1132 and the die 1101 can be facilitated by connections 1133 through the package substrate 1120. The connections 1133 can represent electrical paths formed through the package substrate 1120, such as connections associated with vias and conductors of a multilayer laminated package substrate.

In some embodiments, the packaged module 1100 can also include one or more packaging structures to, for example, provide protection and/or facilitate handling of the packaged module 1100. Such a packaging structure can include overmold or encapsulation structure 1140 formed over the packaging substrate 1120 and the components and die(s) disposed thereon.

FIG. 12 is a schematic diagram of one embodiment of a phone board 1200. The phone board 1200 includes the module 1100 shown in FIGS. 11A-11B or the module 1100 of FIGS. 11C-11D attached thereto. Although not illustrated in FIG. 12 for clarity, the phone board 1200 can include additional components and structures.

### Applications

Some of the embodiments described above have provided examples in connection with wireless devices or mobile phones. However, the principles and advantages of the embodiments can be used for any other systems or apparatus that have needs for power amplifiers.

Such power amplifier system can be implemented in various electronic devices. Examples of the electronic devices can include, but are not limited to, consumer electronic products, parts of the consumer electronic products, electronic test equipment, etc. Examples of the electronic devices can also include, but are not limited to, memory chips, memory modules, circuits of optical networks or other communication networks, and disk driver circuits. The consumer electronic products can include, but are not limited to, a mobile phone, a telephone, a television, a computer monitor, a computer, a hand-held computer, a personal digital assistant (PDA), a microwave, a refrigerator, an automobile, a stereo system, a cassette recorder or player, a DVD player, a CD player, a VCR, an MP3 player, a radio, a camcorder, a camera, a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

### CONCLUSION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A power amplifier system comprising:
a push-pull power amplifier configured to amplify a radio frequency signal, the push-pull power amplifier including a first transistor and a second transistor; and
an output matching network coupled to the push-pull power amplifier to control a harmonic response included in the amplified radio frequency signal, the output matching network including: a balun having a primary coil, each side end of which being connected to the first transistor and the second transistor respectively, and a secondary coil electrically coupled to the primary coil, a feed circuit connected between a center tap of the primary coil and a ground, and first and second shunt capacitors respectively disposed at each side end of the primary coil.

2. The power amplifier system of claim 1 wherein each of the first transistor and the second transistor is bipolar junction transistor (BJT).

3. The power amplifier system of claim 2 wherein a collector of the first transistor is connected to one side end of the primary coil and a collector of the second amplifier is connected to the other side end of the primary coil.

4. The power amplifier system of claim 1 further comprising a decoupling capacitor disposed between the side ends of the primary coil.

5. The power amplifier system of claim 1 wherein the feed circuit includes a capacitor and an inductor connected with each other in series.

6. The power amplifier system of claim 5 wherein the feed circuit is configured to operate as a short circuit at a first frequency.

7. The power amplifier system of claim 6 wherein the feed circuit is configured to operate in a resonance at a second frequency, the second frequency being double the first frequency.

8. The power amplifier system of claim 1 wherein each of the first and second shunt capacitors is configured to be tunable for wider band harmonic control.

9. A radio frequency module comprising:
a packaging board configured to receive a plurality of components;
a power amplifier system implemented on the packaging board, the power amplifier system including: a push-pull power amplifier configured to amplify a radio frequency signal, the push-pull power amplifier including a first transistor and a second transistor; and an output matching network coupled to the push-pull power amplifier to control a harmonic response included in the amplified radio frequency signal, the output matching network including: a balun having a primary coil, each side end of which being connected to the first transistor and the second transistor respectively, and a secondary coil electrically coupled to the primary coil, a feed circuit connected between a center tap of the primary coil and a ground, and first and second shunt capacitors respectively disposed at each side end of the primary coil.

10. The radio frequency module of claim 9 wherein the radio frequency module is a front-end module.

11. The radio frequency module of claim 9 wherein each of the first transistor and the second transistor is bipolar junction transistor (BJT).

12. The radio frequency module of claim 11 wherein a collector of the first transistor is connected to one side end of the primary coil and a collector of the second amplifier is connected to the other side end of the primary coil.

13. The radio frequency module of claim 9 wherein the power amplifier system further includes a decoupling capacitor disposed between the side ends of the primary coil.

14. The radio frequency module of claim 9 wherein the feed circuit includes a capacitor and an inductor connected with each other in series.

15. The radio frequency module of claim 14 wherein the feed circuit is configured to operate as a short circuit at a first frequency.

16. The radio frequency module of claim 15 wherein the feed circuit is configured to operate in a resonance at a second frequency, the second frequency being double the first frequency.

17. The radio frequency module of claim 9 wherein each of the first and second shunt capacitors is configured to be tunable for wider band harmonic control.

18. A mobile device comprising:
a transceiver configured to generate a radio frequency signal; and
a front end system including a power amplifier system configured to amplify the radio frequency signal, the power amplifier system including: a push-pull power amplifier including a first transistor and a second transistor; and an output matching network coupled to the push-pull power amplifier to control a harmonic response included in the amplified radio frequency signal, the output matching network including: a balun having a primary coil, each side end of which being connected to the first transistor and the second transistor respectively, and a secondary coil electrically coupled to the primary coil, a feed circuit connected between a center tap of the primary coil and a ground, and first and second shunt capacitors respectively disposed at each side end of the primary coil.

19. The mobile device of claim 18 wherein each of the first transistor and the second transistor is bipolar junction transistor (BJT).

20. The mobile device of claim 19 wherein a collector of the first transistor is connected to one side end of the primary coil and a collector of the second amplifier is connected to the other side end of the primary coil.
